(19) United States
(12) Patent Application Publication
(10) Pub. No.: US 2006/0273816 A1
(43) Pub. Date: Dec. 7, 2006

(54) Circuit board having a reverse build-up structure

(76) Inventor: Shih-Ping Hsu, Hsin-chu (TW)

Correspondence Address: Mr. Joseph A. Sawyer, Jr.;SAWYER LAW GROUP LLP, Embarcadero Corporate Center, 2465 East Bayshore Road, Suite 406, Palo Alto, CA, 94303, US

(21) Appl. No.: 11/407,485

(22) Filed: Apr. 19, 2006

(30) Foreign Application Priority Data
Jun. 7, 2005 (TW) 094118703

(51) Int. Cl. G01R 31/26

(52) U.S. Cl. 324/765

(57) ABSTRACT

A circuit board having a reverse build-up structure includes a supporting carrier formed with a through cavity; a dielectric layer having a first surface and a second surface opposite to the first surface and being extended into the through cavity, one end of the through cavity being sealed by the first surface; a plurality of electrically contact pads embedded in the dielectric layer and appeared on the first surface of the dielectric layer and corresponding to the through cavity of the supporting carrier; and a circuit layer formed on the second layer of the dielectric layer and electrically connected to the electrically contact pads through a plurality of conductive vias embedded in the dielectric layer.

### CROSS-REFERENCE TO RELATED APPLICATIONS

This application claims benefit under 35 USC 119 of Taiwan Application No. 094118703, filed Jun. 7, 2005.

### FIELD OF THE INVENTION

The present invention relates generally to a circuit board having a reverse build-up structure, and more particularly, to a circuit board having a structure formed with a build-up circuit.

### BACKGROUND OF THE INVENTION

With the explosive development of electronic technologies, an electronic device is more and more compact, and has varieties of functions. In order to satisfy the package demand for microminiaturization and high integrity, a modern circuit board for a plurality of active and passive components to be installed on has a multi-layered structure, so as to comprise as many components as possible through the use of an interlayer connection technique.

FIG. 1A to FIG. 1D are fours cross-sectional schematic diagrams of a core board 1 having two metal layers 11 and a plating through hole (PTH) 13 according to prior art. The core board 1 is drilled to form a hole 12, and the hole 12 is electroplated to form the plating through hole 13. A conductive material is filled with the plating through hole 13 to enabling the metal layers 13 to be electrically connected to each other. After processed by a circuit patterning process, the metal layers 11 become two circuit layers 14, which are also electrically connected to each other. Two circuit build-up structures 15 are then formed on the circuit layers 14 respectively and on the core board 1, so as to form a multi-layered circuit board 10, as shown in FIG. 1D.

The multi-layered circuit board 10 has two circuit build-up structures 15 formed symmetrically to the core board 1. In order to electrically connect the two circuit layers 14, the hole 12 has to be formed on the core circuit 1 by the use of a driller in advance, and then the hole 12 has to be electroplated to form the plating through hole 13. Such a drilling process through the use of the driller and an electroplating process used to electroplate the hole 12 increase a number of steps to manufacture the multi-layered circuit board 10, and therefore increase the cost of the multi-layered circuit board 10.

Moreover, the circuit board 10 has to have the two circuit build-up structures 15 be formed on both sides of the core board 1 respectively to overcome a problem the circuit board 10 may be deformed. Since the two circuit build-up structures 15 are synchronically formed on the core board 1, the two circuit build-up structures 15 are symmetrical and the circuit board 10 has a symmetrical structure. However, for signals transmitted over the circuit board 10, the symmetrical structure is not necessary. During the formation of the two circuit build-up structures 15, two dielectric layers, two circuit layers, and unnecessary circuit layer structures will be formed on the circuit layers 14 accordingly. Such the unnecessary circuit layer structures increase the material consumption and cost of the circuit board 10.

A plurality of solder balls, which are used to be connected to an external electric device, are installed on a outer circuit of each of the circuit build-up structures 15. The more the number of the layers of the circuit build-up structure 15 is, the longer a connection path from the solder balls installed on one side of the circuit build-up structure 15 to a circuit installed on the other side of the circuit build-up structure 15 becomes, and the larger the impedance of the circuit board 10 become. Too large the impedance makes a impact on the performance of the signals transmitted over the circuit board 10.

While operating in a high frequency environment, the circuit board 10 has parasite impedances, which affect the transmission of signals. Therefore, in order to operate normally in such the high frequency environment, the circuit board 10 has to reduce the parasite impedances.

Moreover, the formation of the two circuit build-up structures 15 on the core board 1 on the both sides not only generates the two useless dielectric layers, but also increases the thickness of the circuit board 10. Too thick the circuit board 10 violates a modern principle of compactness.

Therefore, how to simplify the steps to manufacture the multi-layered circuit board 10 and reduce the cost of the multi-layered circuit board 10 has becoming one of the most important design issues in circuit board technologies.

### SUMMARY OF THE INVENTION

Accordingly, it is a primary objective of the present invention to solve the problems of the aforementioned conventional technology by providing a circuit board having a reverse build-up structure, without using a core board or a plating through hole.

It is a secondary objective of the present invention to provide a circuit board having a reverse build-up structure to shorten a conduct circuit, so as to reduce impedances and improve electric characteristics.

It is another objective of the present invention to provide a circuit board having a unidirectional reverse build-up structure, eliminating the need to implement another build-up circuit on a core board and reducing material cost.

It is yet another objective of the present invention to provide a circuit board having a thin reverse build-up structure, so as to satisfy the application trend of compact size.

It is yet another objective of the present invention to provide a circuit board having a reverse build-up structure, so as to attain the requirement of high density of circuit layout.

It is yet another objective of the present invention to provide a circuit board having a reverse build-up structure, capable of utilizing a supporting carrier to strengthen a circuit board or improve a heat-dissipating effect.

In order to attain the object mentioned above and the others, a circuit board having a reverse build-up structure includes a supporting carrier formed with a through cavity; a dielectric layer having a first surface and a second surface opposite to the first surface and the first surface being extended into the through cavity, one end of the through cavity being sealed by the first surface; a plurality of electrically contact pads embedded in the dielectric layer and appeared on the first surface of the dielectric layer and corresponding to the through cavity of the supporting carrier; and a circuit layer formed on the second surface of the dielectric layer and electrically connected to the electrically contact pads through a plurality of conductive via embedded in the dielectric layer.

The circuit board further includes a circuit build-up structure formed on the circuit layer and the second surface of the dielectric layer, the circuit build-up structure having a build-up dielectric layer, a build-up circuit layer formed on the build-up dielectric layer, and a plurality of conductive structures formed in the build-up dielectric layer. A solder mask layer is formed on the circuit build-up structure. The solder mask layer has a plurality of openings for exposure of the electrically connective pads of the circuit build-up structure. A plurality of conductive components are formed in the openings of the solder mask layer and electrically connected to the electrically connective pads.

The dielectric layer, the circuit layer and the circuit build-up structure are all formed on one side of the supporting carrier of the circuit board, and are electrically connected together by the conductive structures of the circuit build-up structure, therefore overcoming the drawback that the prior art has to implement the plating through hole on the core board. Since without the plating through hole, the circuit board has a smaller impedance, and better electric characteristics. Moreover, the circuit build-up structure is installed on the circuit board unidirectionally, the circuit board is thin.

### BRIEF DESCRIPTION OF DRAWINGS

The present invention can be more fully understood by reading the following detailed description of the preferred embodiments, with reference made to the accompanying drawings, wherein:

FIG. 1A to FIG. 1D are fours cross-sectional schematic diagrams of a core board having a plating through hole according to prior art;

FIG. 2 is a cross-sectional schematic diagram of a circuit board having a reverse build-up structure of a first embodiment according to the present invention;

FIG. 3A and FIG. 3B are two partially cross-sectional schematic diagrams of a surface treatment layer formed on a plurality of electrically connective pads of the circuit board shown in FIG. 2;

FIG. 4 is a schematic diagram of a circuit board having a reverse build-up structure of a second embodiment according to the present invention;

FIG. 5 is a schematic diagram of a circuit board having a reverse build-up structure of a third embodiment according to the present invention;

FIG. 6 is a schematic diagram of a circuit board having a reverse build-up structure of a fourth embodiment according to the present invention.

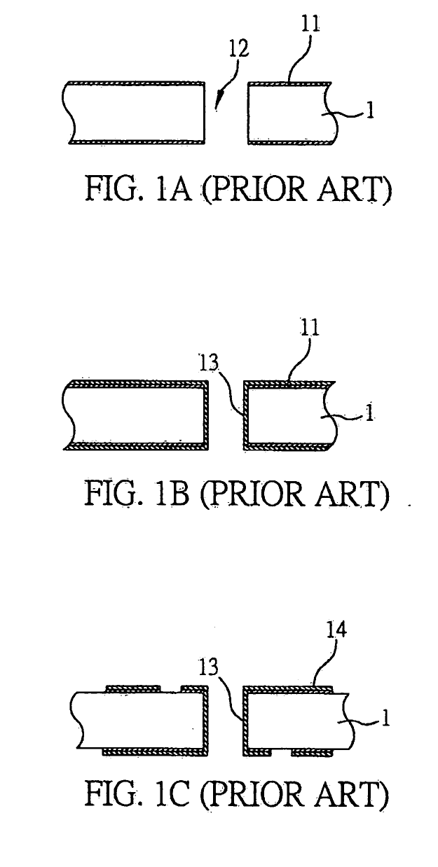

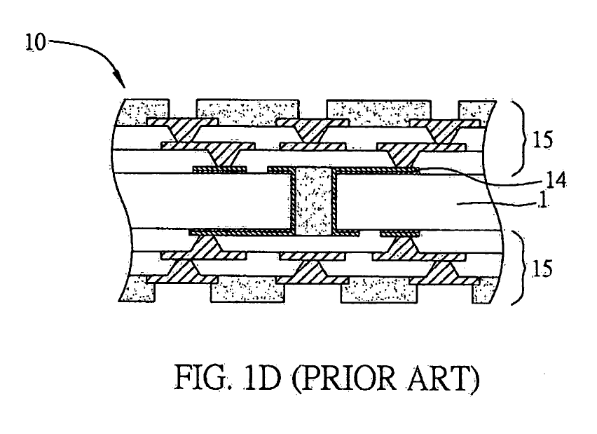

### DETAILED DESCRIPTION OF THE PREFERRED EMBODIMENTS

The following description contains specific information pertaining to the implementation of the present invention. One skilled in the art will readily recognize other advantages and features of the present invention after reviewing what specifically disclosed in the present application. It is manifest that the present invention can be implemented and applied in a manner different from that specifically discussed in the present application. It should also be understood that the invention is not limited to the particular exemplary embodiments described herein, but is capable of many rearrangements, modifications, and substitutions without departing from the spirit of the present invention.

### The First Embodiment

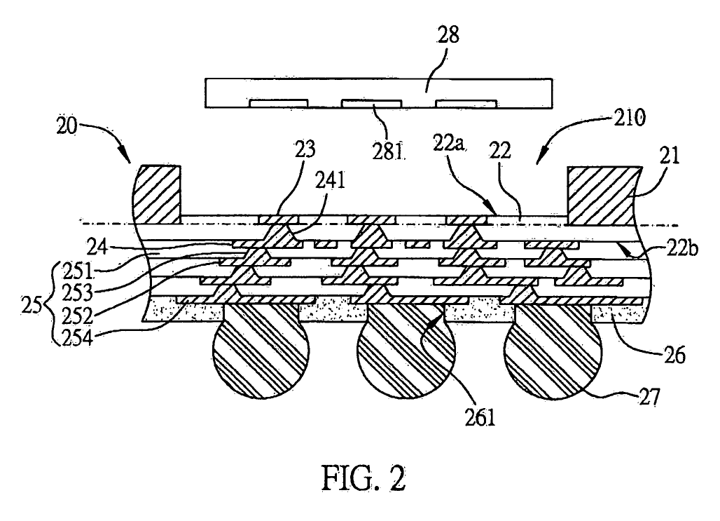

FIG. 2 is a cross-sectional schematic diagram of a circuit board 20 having a reverse build-up structure of a first embodiment according to the present invention. The circuit board 20 comprises a supporting carrier 21 such as a metal board having a heat dissipating functionality, the supporting carrier 21 is formed with at least a through cavity 210. The circuit board 20 further comprises a dielectric layer 22 having a second surface 22b and a first surface 22a opposite to the second surface 22b and extended into the through cavity 210 of the supporting carrier 21. One end of the through cavity 210 is sealed by the first surface 22a. The circuit board 20 further comprises a plurality of electrically contact pads 23 embedded in the dielectric layer 22 and appeared on first surface 22a of the dielectric layer 22 and corresponding to the through cavity 210 of the supporting carrier 21. A circuit layer 24 is formed on the second surface 22b of the dielectric layer 22. A plurality of conductive vias 241 are embedded in the dielectric layer 22 and are electrically connected between the circuit layer 22 and the electrically contact pads 23.

A circuit build-up structure 25 is formed on the dielectric layer 22 and the circuit layer 24. The circuit build-up structure 25 comprises a build-up dielectric layer 251, a build-up circuit layer 252 formed on the build-up dielectric layer 251, and a conductive structure 253 formed in the build-up dielectric layer 251. The conductive structure 253 is electrically connected to the circuit layer 24 on the second surface 22b of the dielectric layer 22 used for sealing the through cavity 210 of the supporting carrier 21, and are electrically connected to electrically contact pads 23. A plurality of electrically connective pads 254 are formed on the circuit build-up structure 25. The conductive via 241 is installed toward a direction from an electrode pad for connecting to a chip to a conductive component, which is different from the traditional arts with another direction from a core board to the electrode pad connected to the chip. A solder mask layer 26 is formed on the circuit build-up structure 25. The solder mask layer 26 comprises a plurality of openings 261 for exposure of the electrically connective pads 254 of the circuit build-up structure 25. A plurality of conductive components 27 are formed in the openings 261 of the solder mask layer 26 and are electrically connected to the electrically connective pad 254. At least one of the conductive components 27 is one selected from the group consisting of a solder ball, a metal bump, and a metal pin.

The through cavity 210 of the supporting carrier 21 is capable of accommodating an active component such as a chip, a passive components such as a resistor, a conductor and a capacitor, and a combination of an active component and a passive component. A plurality of the electrode pads 281 are formed on the chip 28 for connecting to the electrically contact pads 23 in the through cavity 210 of the supporting carrier 21. For example, solder bumps can be formed on the electrode pad 281, so that the chip 28 is capable of electrically connecting to the electrically contact pad 23 of the circuit board 20, enabling the chip 28 in a flip chip manner to connect to the electrically contact pads of the circuit board 20. Of course, the chip 28 can also be installed on the circuit board 20, and is electrically connected to the electrode pads 281 of the circuit board 20 by wire bonding.

The dielectric layer 22, the circuit layer 24 and the circuit build-up structure 25 are all formed on one side of the supporting carrier 21 of the circuit board 20, and are electrically connected together by the conductive structures 253 of the circuit build-up structure 25, therefore overcoming the drawback that the prior art has to implement the plating through hole 13 on the core board 1. Since without the plating through hole 13, the circuit board 20 has a smaller impedance, and better electric characteristics. Moreover, the circuit build-up structure 25 is installed on the circuit board 20 unidirectionally, the circuit board 20 is thin.

Moreover, the supporting carrier 21 is a metal board, and is installed above the dielectric layer 22, so the circuit board 20 has a robust structure and is free from deformation. In conclusion, the circuit board 20 is flat and has a good enough heat dissipating capability.

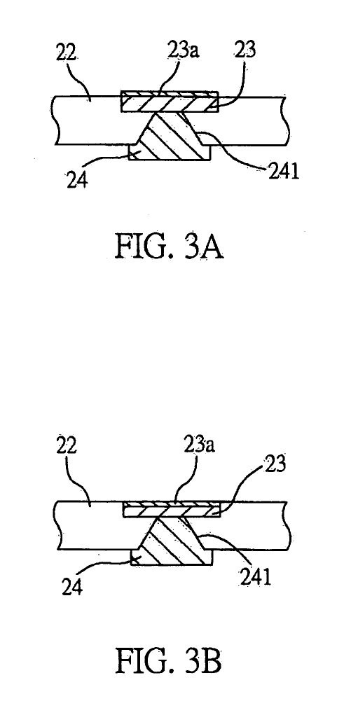

FIG. 3A and FIG. 3B are two partially cross-sectional schematic diagrams of a surface treatment layer 23a formed on the electrically contact pads 23 of the circuit board 20. The surface treatment layer 23a is made of one selected from the group consisting of tin, silver, gold, copper, nickel, lead and platinum, or is an alloy of at least two kinds of metal included in the group, or is an organic solderability preservative (OSP). The surface treatment layer 23a is used to adhere the electrically contact pads 23 to the chip 28. The surface treatment layer 23a has one selected from the group consisting of a first structure protruded to a region outside of the dielectric layer and a second structure even with the dielectric layer.

### The Second Embodiment

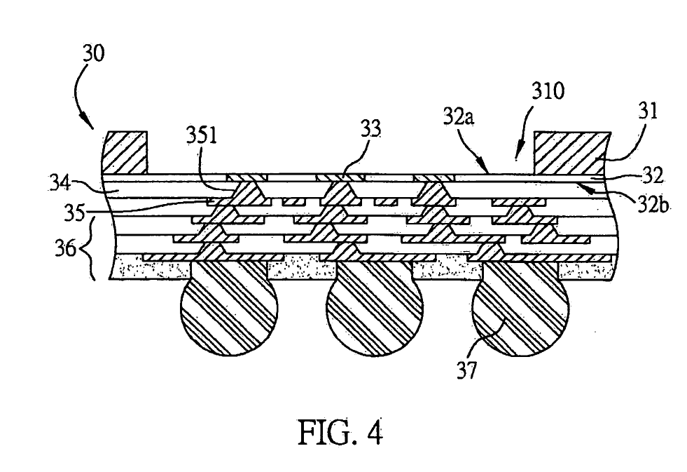

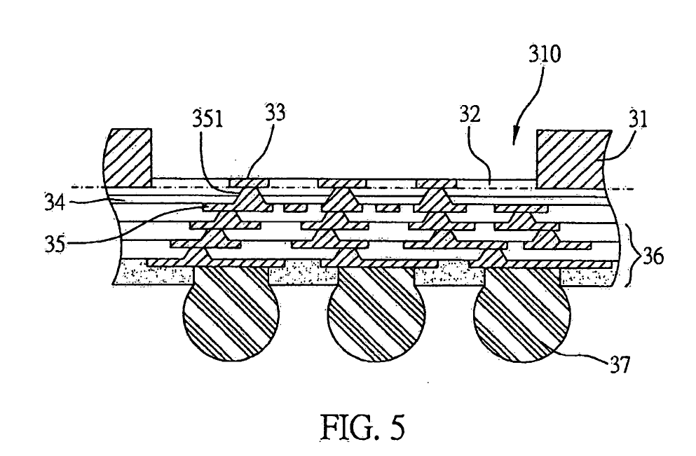

FIG. 4 is a schematic diagram of a circuit board 30 having a reverse build-up structure of a second embodiment according to the present invention. The difference between the second embodiment and the first embodiment is that the dielectric layer of the circuit board 30 is divided into a first dielectric layer and a second dielectric layer. The circuit board 30 comprises a supporting carrier 31 formed with a through cavity 310, and a first dielectric layer 32 having a second surface 32b and a first surface 32a opposite to the second surface 32b, one end of the through cavity 310 of the supporting carrier 31 is sealed by the first surface 32a. The circuit board 30 further comprises a plurality of electrically contact pads 33 formed in the first dielectric layer 32 and appeared on the first surface 32a of the first dielectric layer 32 and corresponding to the through cavity 310 of the supporting carrier 31. A second dielectric layer 34 is formed on the second surface 32 of the first dielectric layer 32. A circuit layer 35 is formed on the second dielectric layer 34 and is electrically connected to the electrically contact pads 33 of the first dielectric layer 32 via a plurality of conductive vias 351 formed in the second dielectric layer 34. The circuit layer 35 does not contact the first dielectric layer 32.

The circuit board 30 further comprises a circuit build-up structure 36 formed on the second dielectric layer 34 and the circuit layer 35 and having a structure the same as a structure of the circuit build-up structure 25, further description hereby omitted. A plurality of conductive components 37 are formed on the circuit build-up structure 36 for connection of an external electronic device.

Since the circuit board 30 does not comprises the core board 1 either, the cost of the circuit board 30 is reduced. Further, since without the plating through hole 13, the circuit board 30 has a smaller impedance, and better electric characteristics. Moreover, the circuit build-up structure 35 is installed on the circuit board 30 unidirectionally, the circuit board 30 is thin.

### The Third Embodiment

FIG. 5 is a schematic diagram of a circuit board having a reverse build-up structure of a third embodiment according to the present invention. The difference between the third embodiment and the previously-mentioned embodiments is that the first dielectric layer 32 is extended into the through cavity 310 of the supporting carrier, and the conductive vias 351 penetrates the first and the second dielectric layers 32,34, and are formed in the first and the second dielectric layers 32,34, and are capable of electrically connecting the electrically contact pads 33 of the first dielectric layer 32. The circuit boards of the third and the second embodiments are similar and have similar merits, further description hereby omitted.

### The Fourth Embodiment

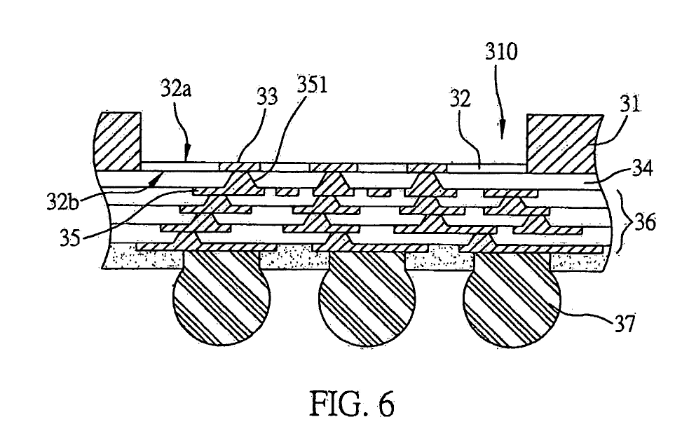

FIG. 6 is a schematic diagram of a circuit board having a reverse build-up structure of a fourth embodiment according to the present invention. The difference between the fourth embodiment and the previously-mentioned embodiments is that the first dielectric layer is installed in the through cavity of the supporting carrier. The circuit board of the fourth embodiment comprises a supporting carrier 31 formed with a through cavity 310, a first dielectric layer 32 having a second surface 32b and a first surface 32a opposite to the second surface 32b and being installed in the through cavity 310 of the supporting carrier 31, a plurality of electrically contact pads 33 formed in the first dielectric layer 32 and appeared on the first surface 32a of the first dielectric layer 32 and corresponding to the through cavity 310 of the supporting carrier 31, a second dielectric layer 34 formed on the second surface 32b of the first dielectric layer 32, and a circuit layer 35 formed on the second dielectric layer 34 and is electrically connected to the electrically contact pads 33 of the first dielectric layer 32 via a plurality of conductive vias 351 embedded in the second dielectric layer 3. The circuit layer 35 does not contact the first dielectric layer 32.

One end of the conductive via 351 of the circuit layer 35 contacting the electrically contact pad 33 has a diameter equal to or smaller than that of the other end of the conducting via 351 of the circuit layer 35 not contacting the electrically contact pad 33.

A circuit build-up structure 36 and a plurality of conductive components 37 are formed on the second dielectric layer 34 and the circuit layer 35 for connection of an external electronic device.

Further, a surface treatment layer (not shown) can be formed on the electrically contact pad 33, and is protruded to a region above the first dielectric layer 32.

Since without the plating through hole 13, the circuit board of the fourth embodiment has a smaller impedance, and better electric characteristics. Moreover, the circuit build-up structure 35 is installed on the circuit board 30 unidirectionally, the circuit board 30 is thin.

The above-described exemplary embodiments are to describe various objects and features of the present invention as illustrative and not restrictive. A person of ordinary skill in the art would recognize that changes could be made in form and detail without departing from the sprit and the scope of the invention. Thus, the right protection scope of the present invention should fall within the appended claim.

What is claimed is:

1. A circuit board having a reverse build-up structure, the circuit board comprising:
a supporting carrier formed with a through cavity;
a dielectric layer having a first surface and a second surface opposite to the first surface and being extended into the through cavity, one end of the through cavity being sealed by the first surface;
a plurality of electrically contact pads embedded in the dielectric layer and appeared on the first surface of the dielectric layer and corresponding to the through cavity of the supporting carrier; and
a circuit layer formed on the second layer of the dielectric layer and electrically connected to the electrically contact pads through a plurality of conductive vias embedded in the dielectric layer.

2. The circuit board of claim 1 further comprising a surface treatment layer formed on the electrically contact pads.

3. The circuit board of claim 2, wherein the surface treatment layer is made of one selected from the group consisting of tin, silver, gold, copper, nickel, lead and platinum, or is an alloy of at least two kinds of metal included in the group.

4. The circuit board of claim 2, wherein the surface treatment layer comprises a plurality of metal layers, each of the metal layers being made of one selected from the group consisting of tin, silver, gold, copper, nickel, lead and platinum.

5. The circuit board of claim 2, wherein the surface treatment layer is an organic solderability preservative (OSP).

6. The circuit board of claim 2, wherein the surface treatment layer has one selected from the group consisting of a first structure protruded to a region outside of the dielectric layer and a second structure even with the dielectric layer.

7. The circuit board of claim 1 further comprising a circuit build-up structure formed on the circuit layer and the second surface of the dielectric layer, the circuit build-up structure comprising a build-up dielectric layer, a build-up circuit layer formed on the build-up dielectric layer, and a plurality of conductive structures formed in the build-up dielectric layer.

8. The circuit board of claim 7 further comprising a solder mask layer formed on the circuit build-up structure, the solder mask layer comprising a plurality of openings for exposure of the electrically connective pads of the circuit build-up structure.

9. The circuit board of claim 8 further comprising a plurality of conductive components formed in the openings of the solder mask layer and electrically connected to the electrically connective pads.

10. The circuit board of claim 9, wherein at least one of the conductive components is one selected from the group consisting a solder ball, a metal bump and a metal pin.

11. The circuit board of claim 1, wherein the supporting carrier is a metal board.

12. A circuit board having a reverse build-up structure, the circuit board comprising:
a supporting carrier formed with a through cavity and a supporting surface;
a first dielectric layer having a first surface and a second surface opposite to the first surface and being extended into the through cavity, the supporting surface and one end of the through cavity being sealed by the first surface;
a plurality of electrically contact pads embedded in the first dielectric layer and appeared on the first surface of the first dielectric layer and corresponding to the through cavity of the supporting carrier;
a second dielectric layer formed on the second surface of the first dielectric layer; and
a circuit layer formed on the second dielectric layer and electrically connected to the electrically contact pads through a plurality of conductive vias embedded in the second dielectric layer, the circuit layer without contacting the first dielectric layer.

13. The circuit board of claim 12, the first surface of the first dielectric layer is extended to the through cavity of the supporting carrier, and the conductive vias are embedded in the first and the second dielectric layers and are electrically connected to the electrically contact pads embedded in the first dielectric layer.

14. The circuit board of claim 12 further comprising a surface treatment layer formed on the electrically contact pads.

15. The circuit board of claim 14, wherein the surface treatment layer is made of one selected from the group consisting of tin, silver, gold, copper, nickel, lead and platinum, or is an alloy of at least two kinds of metal included in the group.

16. The circuit board of claim 14, wherein the surface treatment layer comprises a plurality of metal layers, each of the metal layers being made of one selected from the group consisting of tin, silver, gold, copper, nickel, lead and platinum.

17. The circuit board of claim 14, wherein the surface treatment layer is an organic solderability preservative.

18. The circuit board of claim 14, wherein the surface treatment layer has one selected from the group consisting of a first structure protruded to a region outside of the first dielectric layer and a second structure even with the first dielectric layer.

19. The circuit board of claim 12 further comprising a circuit build-up structure formed on the circuit layer and the second dielectric layer, the circuit build-up structure comprising a build-up dielectric layer, a build-up circuit layer formed on the build-up dielectric layer, and a plurality of conductive structures formed in the build-up dielectric layer.

20. The circuit board of claim 19 further comprising a solder mask layer formed on the circuit build-up structure, the solder mask layer comprising a plurality of openings for exposure of the electrically connective pads of the circuit build-up structure.

21. The circuit board of claim 20 further comprising a plurality of conductive components formed in the openings of the solder mask layer and electrically connected to the electrically connective pads.

22. The circuit board of claim 21, wherein at least one of the conductive components is one selected from the group consisting a solder ball, a metal bumps and a metal pin.

23. The circuit board of claim 12, wherein the supporting carrier is a metal board.

24. A circuit board having a reverse build-up structure, the circuit board comprising:
a supporting carrier formed with a through cavity and a supporting surface;
a first dielectric layer embedded in the through cavity of the supporting carrier, the first dielectric layer having a first surface and a second surface opposite to the first surface;
a plurality of electrically contact pads embedded in the first dielectric layer and appeared on the first surface of the first dielectric layer and corresponding to the through cavity of the supporting carrier;
a second dielectric layer formed on the supporting carrier and the second surface of the first dielectric layer; and
a circuit layer formed on the second dielectric layer and electrically connected to the electrically contact pads through a plurality of conductive vias embedded in the second dielectric layer, the circuit layer without contacting the first dielectric layer.

25. The circuit board of claim 24, wherein one end of the conducting via of the circuit layer contacting the electrically contact pad has a radius equal to or smaller than that of the other end of the conducting via of the circuit layer not contacting the electrically contact pad.

26. The circuit board of claim 24 further comprising a surface treatment layer formed on the electrically contact pads.

27. The circuit board of claim 26, wherein the surface treatment layer is made of one selected from the group consisting of tin, silver, gold, copper, nickel, lead and platinum, or is an alloy of at least two kinds of metal included in the group.

28. The circuit board of claim 26, wherein the surface treatment layer comprises a plurality of metal layers, each of the metal layers being made of one selected from the group consisting of tin, silver, gold, copper, nickel, lead and platinum.

29. The circuit board of claim 28, wherein the surface treatment layer is an organic solderability preservative.

30. The circuit board of claim 28, wherein the surface treatment layer has a structure protruded to a region outside of the first dielectric layer.

31. The circuit board of claim 24 further comprising a circuit build-up structure formed on the circuit layer and the second dielectric layer, the circuit build-up structure comprising a build-up dielectric layer, a build-up circuit layer formed on the build-up dielectric layer, and a plurality of conductive structures formed in the build-up dielectric layer.

32. The circuit board of claim 31 further comprising a solder mask layer formed on the circuit build-up structure, the solder mask layer comprising a plurality of openings for exposure of the electrically connective pads of the circuit build-up structure.

33. The circuit board of claim 32 further comprising a plurality of conductive components formed in the openings of the solder mask layer and electrically connected to the electrically connective pads.

34. The circuit board of claim 33, wherein at least one of the conductive components is one selected from the group consisting a solder ball, a metal bump and a metal pin.

35. The circuit board of claim 33, wherein the supporting carrier is a metal board.
